(19) United States
(12) Patent Application Publication
(10) Pub. No.: US 2023/0183415 A1
(43) Pub. Date: Jun. 15, 2023

(54) PRIMER, SUBSTRATE EQUIPPED WITH PRIMER LAYER, METHOD FOR PRODUCING SUBSTRATE EQUIPPED WITH PRIMER LAYER, SEMICONDUCTOR DEVICE, AND METHOD FOR PRODUCING SEMICONDUCTOR DEVICE

(71) Applicant: Showa Denko Materials Co., Ltd., Tokyo (JP)

(72) Inventors: Ning TANG, Chiyoda-ku, Tokyo (JP); Shingo TANAKA, Chiyoda-ku, Tokyo (JP); Yoshitaka TAKEZAWA, Chiyoda-ku, Tokyo (JP)

(73) Assignee: Showa Denko Materials Co., Ltd., Tokyo (JP)

(21) Appl. No.: 17/925,014

(22) PCT Filed: May 13, 2021
(86) PCT No.: PCT/JP2021/018255

§ 371 Date: Nov. 14, 2022

(30) Foreign Application Priority Data
May 14, 2020 (JP) 2020-085320

(51) Int. Cl. C08G 59/24; C08G 59/62; C09K 19/30; C08G 59/50; H01L 23/373

(52) U.S. Cl. CPC C08G 59/245; C08G 59/62; C09K 19/3068; C08G 59/50; H01L 23/3737; C09K 2019/3075

(57) ABSTRACT

A primer for forming a primer layer on the surface of a substrate having surface free energy of 50 mN/m or higher, the primer including a liquid crystalline epoxy compound and a curing agent.

### TECHNICAL FIELD

The present invention relates to a primer, a substrate equipped with a primer layer, a method for producing a substrate equipped with a primer layer, a semiconductor device, and a method for producing a semiconductor device.

### BACKGROUND ART

Along with an increase in energy density due to the size reduction and performance enhancement of electronics, the amount of heat generated per unit volume tends to increase. Therefore, to devices from which a large amount of heat is generated such as inverters that are used for the control of motors of electric vehicles, heat dissipation members such as heat sinks and fins for guaranteeing stable operation are indispensable. Furthermore, as means for binding chips and heat sinks or the like, materials being excellent in terms of insulating properties and heat dissipation properties are in demand.

Usually, resins have excellent insulating properties, but have low thermal conductivity and poor heat dissipation properties. Therefore, Japanese Patent Laid-Open No. 2009-21530 describes a sheet-like adhesive having heat dissipation properties enhanced by adding an inorganic filler to a resin.

### SUMMARY OF INVENTION

### Technical Problem

Addition of an inorganic filler to a resin is effective for improvement in heat dissipation properties, but causes a problem of a decrease in adhesive strength to surfaces to which the adhesive adheres. Therefore, in the invention described in Japanese Patent Laid-Open No. 2009-21530, adhesive layers containing no inorganic fillers are disposed on both sides of an adhesive layer containing an inorganic filler to increase the adhesive strength to surfaces to which the adhesive adheres; however, in this method, the production cost of the adhesive increases.

In consideration of the above-described circumstances, an objective of the present invention is to provide a primer exhibiting excellent thermal conductive properties even without including an inorganic filler. Another objective of the present invention is to provide a substrate equipped with a primer layer that is obtained using this primer, a production method thereof, a semiconductor device and a production method thereof.

### Solution to Problem

Specific means for achieving the above-described objectives is as described below.

<1> A primer for forming a primer layer on a surface of a substrate having a surface free energy of 50 mN/m or higher, the primer including a liquid crystalline epoxy compound and a curing agent.

<2> The primer according to <1>, in which the liquid crystalline epoxy compound includes at least one of a structure represented by the following general formula (M-1) and a structure represented by the following general formula (M-2).

### [Chem. 1]

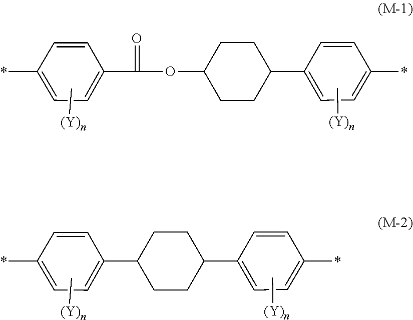

In the general formula (M-1) and the general formula (M-2), Y's each independently represent an aliphatic hydrocarbon group having 1 to 8 carbon atoms, an alkoxy group having 1 to 8 carbon atoms, a fluorine atom, a chlorine atom, a bromine atom, an iodine atom, a cyano group, a nitro group or an acetyl group, n's each independently represent an integer of 0 to 4, and * represents a bonding site to an adjacent atom.

<3> The primer according to <2>, in which the crystalline epoxy compound includes a reaction product between a liquid crystalline epoxy compound including at least one of the structure represented by the general formula (M-1) and the structure represented by the general formula (M-2) and at least one selected from the group consisting of hydroquinone, 3,3-biphenol, 4,4-biphenol, 2,6-naphthalenediol, 1,5-naphthalenediol, 4-hydroxybenzoic acid and 2-hydroxy-6-naphthoic acid.

<4> The primer according to any one of <1> to <3>, in which the curing agent includes at least one selected from the group consisting of an amine-based curing agent and a phenolic curing agent.

<5> The primer according to any one of <1> to <4>, in which a liquid crystalline structure that is formed by a reaction between the liquid crystalline epoxy compound and the curing agent is a nematic structure or a smectic structure.

<6> The primer according to <5>, in which the smectic structure has a periodic structure in which a length of one period is 2 nm to 4 nm.

<7> The primer according to any one of <1> to <6>, including an alcohols solvent.

<8> The primer according to any one of <1> to <7>, in which the substrate is a metal substrate.

<9> A substrate equipped with a primer layer including a substrate and a primer layer, in which the primer layer is a cured product of the primer according to any one of <1> to <8>, and a surface free energy of a surface of the substrate facing the primer layer is 50 mN/m or higher.

<10> A method for producing a substrate equipped with a primer layer, the method including a step of forming a layer including the primer according to any one of <1> to <8> on a substrate and a step of forming a primer layer by curing the layer including the primer, in which a surface free energy of a surface of the substrate facing the primer layer is 50 mN/m or higher.

<11> A semiconductor device including a substrate, a primer layer, and an insulating member in this order, in which the primer layer is a cured product of the primer according to any one of <1> to <8>, and a surface free energy of a surface of the substrate facing the primer layer is 50 mN/m or higher.

<12> A method for producing a semiconductor device, the method including a step of forming a layer including the primer according to any one of <1> to <8> on a substrate, a step of disposing an insulating member on the layer including the primer, and a step of forming a primer layer by curing the layer including the primer, in which a surface free energy of a surface of the substrate facing the primer layer is 50 mN/m or higher.

### Advantageous Effects of Invention

According to the present invention, a primer exhibiting excellent thermal conductive properties even without including an inorganic filler is provided.

Furthermore, according to the present invention, a substrate equipped with a primer layer that is obtained using this primer, a production method thereof, a semiconductor device and a production method thereof are provided.

### BRIEF DESCRIPTION OF DRAWINGS

FIG. 1 is a schematic cross-sectional view showing an example of the configuration of a semiconductor device.

### DESCRIPTION OF EMBODIMENTS

Hereinafter, embodiments for carrying out the present invention will be described in detail. However, the present invention is not limited to the following embodiments. In the following embodiments, configuration elements (also including element steps and the like) are not essential unless particularly clearly specified. This is also true for numerical values and ranges thereof, and configuration elements, numerical values, and ranges thereof do not limit the present invention.

The term “step” in the present disclosure refers not only to a step independent of other steps but also to a step that cannot be clearly differentiated from other steps as long as the intended purpose of the step is achieved.

Numerical ranges expressed using “to” in the present disclosure include numerical values before and after “to” as the minimum value and the maximum value, respectively.

In numerical ranges expressed stepwise in the present disclosure, the upper limit value or the lower limit value described in one numerical range may be substituted for the upper limit value or the lower limit value of a different numerical range expressed stepwise. In addition, in a numerical range expressed in the present disclosure, the upper limit value or the lower limit value of the numerical range may be substituted for a value described in an example.

Each component in the present disclosure may contain a plurality of kinds of corresponding substances. In a case where there is a plurality of kinds of substances corresponding to each component in a composition, unless particularly otherwise described, the content rate or content of each component refers to the total content rate or content of the plurality of kinds of substances present in the composition.

At the time of observing a region in which a certain film is present, the term “film” in the present disclosure refers not only to a film that is formed throughout the entire region but also to a film that is formed only in a part of the region.

In the present disclosure, an average thickness is a value that is provided as an arithmetic average value after the thickness of a subject is measured at five arbitrarily-selected points. The thickness can be measured using a micrometer or the like.

<Primer>

A primer of the present disclosure is a primer for forming a primer layer on the surface of a substrate having a surface free energy of 50 mN/m or higher, the primer including a liquid crystalline epoxy compound and a curing agent.

As a result of studies, the present inventors found that a primer layer that is formed on the surface of a substrate having a surface free energy of 50 mN/m or higher using a primer including a liquid crystalline epoxy compound and a curing agent exhibits excellent thermal conductive properties even without including an inorganic filler. The reason therefor is considered that, in the primer layer that is formed by the curing of the primer, a structure in which the molecules of the liquid crystalline epoxy compound are arranged in a direction perpendicular to the surface of the substrate is formed.

More specifically, the reason is considered as described below. Hydroxyl groups that are present on the surface of the substrate having a surface free energy of 50 mN/m or higher and an epoxide of the liquid crystalline epoxy compound form chemical bonds (hydrogen bonds), which makes it easy for the molecules of the epoxy compound to be in a state of being arranged in a direction perpendicular to the surface of the substrate. As a result, heat is transferred from the surface of the primer layer on the substrate side to the opposite surface along covalent bonds that connect the molecules of the liquid crystalline epoxy compound by phonons, which are a transport medium of heat.

Hereinafter, the components of the primer will be described in detail.

(Liquid Crystalline Epoxy Compound)

The primer includes a liquid crystalline epoxy compound. “Liquid crystalline epoxy compound” in the present disclosure means an epoxy compound having a property of forming a liquid crystalline structure by reacting with a curing agent.

The liquid crystalline structure that is formed by a reaction of the liquid crystalline epoxy compound with a curing agent is a higher-order structure exhibiting liquid crystallinity among higher-order structures in which the regularity of the state of the molecules of the epoxy compound being arranged at the time of the reaction is high (also referred to as a periodic structure).

Whether or not the liquid crystalline structure has been formed in a cured product can be directly confirmed by, for example, observation with a polarizing microscope under crossed-Nicols or an X-ray scattering method. Alternatively, the presence of the liquid crystalline structure can be indirectly confirmed by measuring a change in the storage modulus of the cured product with respect to the temperature using a property of the storage modulus that changes to a small extent with respect to the temperature when the liquid crystalline structure is present in the cured product.

Examples of the liquid crystalline structure that is formed in the cured product include a nematic structure, a smectic structure and the like. The nematic structure is a liquid crystalline structure having an orientational order alone in which long molecular axes are oriented in a uniform direction. In contrast, the smectic structure is a liquid crystalline structure having not only an orientational order but also a one-dimensional positional order and having a layer structure with a constant period. In addition, in the same periodic structures of the smectic structure, the directions of the periods of the layer structures are uniform.

The smectic structure that is formed in the cured product preferably has a periodic structure with a length of one period (period length) being 2 nm to 4 nm. The length of one period being 2 nm to 4 nm makes it possible to exhibit higher thermal conductivity.

The length of one period in the periodic structure can be measured using a wide angle X-ray diffractometer (for example, manufactured by Rigaku Corporation, trade name: “RINT2500HL”). Specifically, the length of one period can be obtained by carrying out X-ray diffraction on a semi-cured product or cured product of an epoxy resin composition as a measurement sample under the following conditions and converting a diffraction angle that is obtained by the X-ray diffraction using the following Bragg's equation.

### (Measurement Conditions)

X-ray source: Cu
X-ray output: 50 kV, 250 mA
Divergence split: 1.0 degree
Scattering split: 1.0 degree
Receiving split: 0.3 mm
Scanning rate: 1.0 degree/minute

Bragg's equation: 2d sin θ=nλ

Here, d indicates the length of one period, θ indicates the diffraction angle, n indicates the reflection order, and λ indicates the wavelength of the X-ray (0.15406 nm).

From the viewpoint of improving the thermal conductive properties, the liquid crystalline epoxy compound preferably has a property of reacting with a curing agent to form a smectic structure.

Examples of the liquid crystalline epoxy compound include an epoxy compound having a so-called mesogenic structure in the molecule. Examples of the mesogenic structure include a biphenyl group, a terphenyl group, a terphenyl analogous group, an anthracene group, a group in which the above-described groups are connected together through an azomethine group or an ester group and the like.

Examples of the epoxy compound having the mesogen structure include epoxy compounds having a structure represented by the following general formula (M).

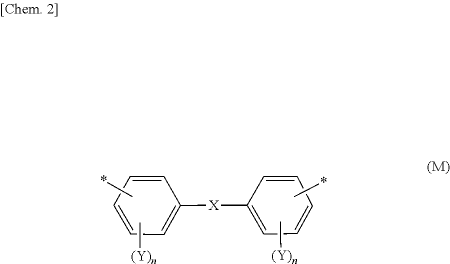

In the general formula (M), X represents a single bond or at least one linking group selected from a group (A) consisting of the following divalent groups. Y's each independently represent an aliphatic hydrocarbon group having 1 to 8 carbon atoms, an alkoxy group having 1 to 8 carbon atoms, a fluorine atom, a chlorine atom, a bromine atom, an iodine atom, a cyano group, a nitro group or an acetyl group. n's each independently represent an integer of 0 to 4. * represents a bonding site to an adjacent atom.

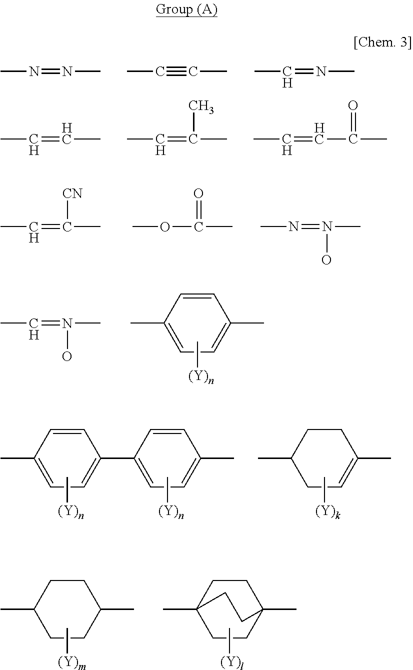

In the group (A), Y's each independently represent an aliphatic hydrocarbon group having 1 to 8 carbon atoms, an alkoxy group having 1 to 8 carbon atoms, a fluorine atom, a chlorine atom, a bromine atom, an iodine atom, a cyano group, a nitro group or an acetyl group. n's each independently represent an integer of 0 to 4, k represents an integer of 0 to 7, m represents an integer of 0 to 8, and 1 represents an integer of 0 to 12.

Y's in the group (A) are each independently preferably absent (n, k, m or l is zero) or an alkyl group having 1 to 3 carbon atoms or more preferably absent or a methyl group.

In the structure represented by the general formula (M), in a case where X is at least one linking group selected from the group (A) consisting of the above-described divalent groups, X is preferably at least one linking group selected from a group (Aa) consisting of the following divalent groups and more preferably at least one linking group that is selected from the group (Aa) and includes at least one cyclic structure.

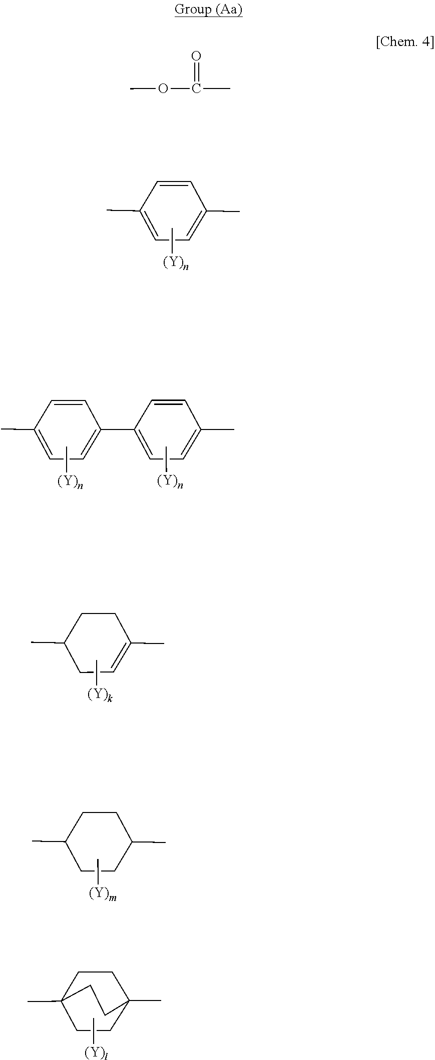

In the group (Aa), Y's each independently represent an aliphatic hydrocarbon group having 1 to 8 carbon atoms, an alkoxy group having 1 to 8 carbon atoms, a fluorine atom, a chlorine atom, a bromine atom, an iodine atom, a cyano group, a nitro group or an acetyl group. n's each independently represent an integer of 0 to 4, k represents an integer of 0 to 7, m represents an integer of 0 to 8, and 1 represents an integer of 0 to 12.

Y's in the group (Aa) are each independently preferably absent (n, k, m or l is zero) or an alkyl group having 1 to 3 carbon atoms or more preferably absent or a methyl group.

Preferable examples of the mesogen structure represented by the general formula (M) include a biphenyl structure and structures in which three or more six-membered ring groups are linearly linked together, and more preferable examples thereof include mesogen structures represented by the following general formula (M-1) and general formula (M-2). In the general formula (M-1) and the general formula (M-2), the definitions and preferable examples of Y, n and * are the same as the definitions and preferable examples of Y, n and * of the general formula (M).

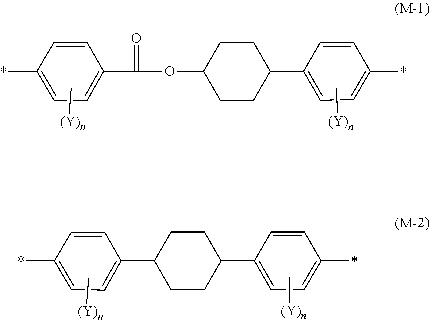

From the viewpoint of forming a structure in which the molecules of the liquid crystalline epoxy compound are arranged in the cured product, in the liquid crystalline epoxy compound, the number of epoxy groups per molecule is preferably two, and the two epoxy groups are more preferably present at positions where the distance therebetween is maximized (for example, both ends of the mesogen structure).

The number of the mesogen structures per molecule of the liquid crystalline epoxy compound is not particularly limited.

Hereinafter, a liquid crystalline epoxy compound in which the number of the mesogen structures per molecule is one will be referred to as “liquid crystalline epoxy monomer”, and a liquid crystalline epoxy compound in which the number of the mesogen structures per molecule is two or more will be referred to as “liquid crystalline epoxy prepolymer” in some cases.

From the viewpoint of forming the liquid crystalline structure in the primer layer, the primer preferably includes a liquid crystalline epoxy monomer represented by the following general formula (1) or general formula (2). The liquid crystalline epoxy monomer represented by the general formula (1) or the general formula (2) may be used singly or two or more liquid crystalline epoxy monomers may be jointly used.

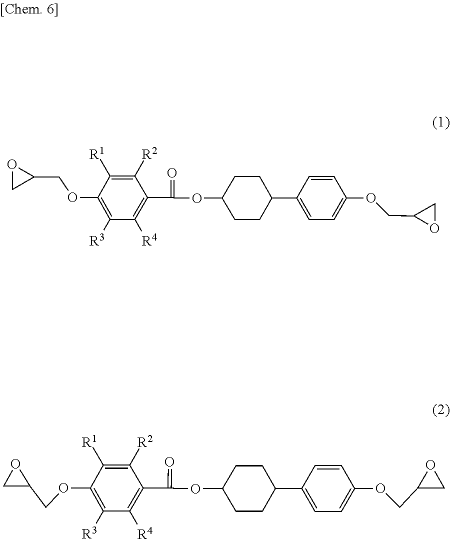

In the general formula (1), R¹ to R⁴ each independently represent a hydrogen atom or an alkyl group having 1 to 3 carbon atoms. R¹ to R⁴ are each independently preferably a hydrogen atom or an alkyl group having 1 or 2 carbon atoms, more preferably a hydrogen atom or a methyl group and still more preferably a hydrogen atom. In addition, among R¹ to R⁴, two to four are preferably a hydrogen atom, three or four are more preferably a hydrogen atom, and all four are still more preferably a hydrogen atom. In a case where any of R¹ to R⁴ is an alkyl group having 1 to 3 carbon atoms, at least one of R¹ and R⁴ is preferably an alkyl group having 1 to 3 carbon atoms.

In the general formula (2), R⁵ to R⁸ each independently represent a hydrogen atom or an alkyl group having 1 to 3 carbon atoms. R⁵ to R⁸ are each independently preferably a hydrogen atom or an alkyl group having 1 or 2 carbon atoms, more preferably a hydrogen atom or a methyl group and still more preferably a hydrogen atom. In addition, among R⁵ to R⁸, two to four are preferably a hydrogen atom, three or four are more preferably a hydrogen atom, and all four are still more preferably a hydrogen atom. In a case where any of R⁵ to R⁸ is an alkyl group having 1 to 3 carbon atoms, at least one of R⁵ and R⁸ is preferably an alkyl group having 1 to 3 carbon atoms.

Preferable examples of the liquid crystalline epoxy monomer represented by the general formula (1) include 4-{4-(2,3-epoxypropoxy)phenyl}cyclohexyl=4-(2,3-epoxypropoxy)benzoate and 4-[4-(2,3-epoxypropoxy)phenyl]cyclohexyl=4-(2,3-epoxypropoxy)-3-methylbenzoate.

Preferable examples of the liquid crystalline monomer represented by the general formula (2) include 1-(3-methyl-4-oxiranylmethoxyphenyl)-4-(oxiranylmethoxyphenyl)-1-cyclohexene.

The primer of the present disclosure may include only the liquid crystalline epoxy monomer, may include only the liquid crystalline epoxy prepolymer or may include both the liquid crystalline epoxy monomer and the liquid crystalline epoxy prepolymer.

Primer layers that are formed using the primer in which at least a part of the liquid crystalline epoxy compound is the liquid crystalline epoxy prepolymer tend to exhibit a high adhesive strength compared with primer layers that are formed using the primer in which all of the liquid crystalline epoxy compound is the liquid crystalline epoxy monomer.

Liquid crystalline prepolymers can be obtained by, for example, reacting the liquid crystalline epoxy monomer and a compound having a functional group capable of reacting with an epoxy group in the liquid crystalline epoxy monomer (hereinafter, also referred to as the prepolymerization agent).

Examples of the functional group in the prepolymerization agent include a hydroxyl group, a carboxy group, an amino group and the like. The prepolymerization agent is preferably a compound having two functional groups in one molecule (bi-functional compound).

The prepolymerization agent is preferably a compound including an aromatic ring (aromatic compound). Examples of the aromatic ring include a benzene ring, a naphthalene ring and the like, and two benzene rings may form a biphenyl structure.

Specific examples of the prepolymerization agent include dihydroxybenzene compounds having a structure in which two hydroxyl groups bond to one benzene ring such as 1,2-dihydroxybenzene (catechol), 1,3-dihydroxybenzene (resorcinol), 1,4-dihydroxybenzene (hydroquinone) and derivatives thereof;

dicarboxybenzene compounds having a structure in which two carboxy groups bond to one benzene ring such as terephthalic acid, isophthalic acid, orthophthalic acid and derivatives thereof;

diaminobenzene compounds having a structure in which two amino groups bond to one benzene ring such as 1,2-diaminobenzene, 1,3-diaminobenzene, 1,4-diaminobenzene and derivatives thereof;

hydroxybenzoic acids having a structure in which one hydroxyl group and one carboxy group bond to one benzene ring such as 4-hydroxybenzoic acid, 3-hydroxybenzoic acid, 2-hydroxybenzoic acid and derivatives thereof;

hydroxybenzoic acids having a structure in which one amino group and one carboxy group bond to one benzene ring such as 4-aminobenzoic acid, 3-aminobenzoic acid, 2-aminobenzoic acid and derivatives thereof;

dihydroxybiphenyl compounds having a structure in which one hydroxyl group bonds to each of two benzene rings that form a biphenyl structure such as 2,2′-dihydroxybiphenyl, 2,3′-dihydroxybiphenyl, 2,4′-dihydroxybiphenyl, 3,3′-dihydroxybiphenyl, 3,4′-dihydroxybiphenyl, 4,4′-dihydroxybiphenyl and derivatives thereof;

dihydroxybiphenyl compounds having a structure in which one carboxy group bonds to each of two benzene rings that form a biphenyl structure such as 2,2′-dicarboxybiphenyl, 2,3′-dicarboxybiphenyl, 2,4′-dicarboxybiphenyl, 3,3′-dicarboxybiphenyl, 3,4′-dicarboxybiphenyl, 4,4′-dicarboxybiphenyl and derivatives thereof;

diaminobiphenyl compounds having a structure in which one amino group bonds to each of two benzene rings that form a biphenyl structure such as 2,2′-diaminobiphenyl, 2,3′-diaminobiphenyl, 2,4′-diaminobiphenyl, 3,3′-diaminobiphenyl, 3,4′-diaminobiphenyl, 4,4′-diaminobiphenyl and derivatives thereof;

naphthalenediol compounds having a structure in which two hydroxyl groups bond to a naphthalene ring such as 2,6-naphthalenediol, 1,5-naphthalenediol and derivatives thereof;

hydroxynaphthalenecarboxylic acids having a structure in which one hydroxyl group and one carboxy group bond to a naphthalene ring such as 2-hydroxy-6-naphthoic acid, 6-hydroxy-2-naphthoic acid and derivatives thereof; and the like.

Examples of the derivatives of the aromatic compound include compounds having an alkyl group having 1 to 8 carbon atoms or the like as a substituent in an aromatic ring.

From the viewpoint of improving the thermal conductivity of the primer layer, among the above-described prepolymerization agents, hydroquinone, 3,3-biphenol, 4,4-biphenol, 2,6-naphthalenediol, 1,5-naphthalenediol, 4-hydroxybenzoic acid and 2-hydroxy-6-naphthoic acid are preferable, and compounds in which two functional groups are in a point-symmetric positional relationship such as 4,4-biphenol and 1,5-naphthalenediol are preferable. In prepolymers that are obtained using the compound in which two functional groups are in a point-symmetric positional relationship, it is considered that the molecular structure becomes linear, the stackability of the molecules is high and a higher-order structure is likely to be formed in cured products.

Furthermore, in prepolymers that are obtained using a compound in which two functional groups are present at Position 1 and Position 5 of naphthalene, there is a tendency that the free volume is small and the crosslinking density becomes high.

The prepolymerization agent that is reacted with the liquid crystalline epoxy monomer may be used singly or two or more prepolymerization agents may be jointly used.

The molecular weight, content percentage or the like of a prepolymer to be obtained can be controlled by adjusting the amount of the prepolymerization agent that is reacted with the liquid crystalline epoxy monomer.

For example, a prepolymer may be obtained by reacting the liquid crystalline epoxy monomer and the prepolymerization agent such that the equivalent ratio (epoxy group/functional group) of the epoxy group of the liquid crystalline epoxy monomer to the functional group of the prepolymerization agent reaches 100/5 to 100/35 or a prepolymer may be obtained by reacting the liquid crystalline epoxy monomer and the prepolymerization agent such that the equivalent ratio reaches 100/15 to 100/25.

From the viewpoint of handleability as the prepolymer, the primer preferably includes a prepolymer composed of two to four molecules of the liquid crystalline epoxy monomer and the prepolymerization agent (dimer to tetramer), more preferably includes a prepolymer composed of two or three molecules of the liquid crystalline epoxy monomer and the prepolymerization agent (dimer or trimer), and still more preferably includes a prepolymer composed of two molecules of the liquid crystalline epoxy monomer and the prepolymerization agent (dimer).

Whether or not the primer includes the prepolymer can be determined by, for example, a well-known method such as gel permeation chromatography.

The total content percentage of the liquid crystalline epoxy compound and the curing agent that are included in the primer is preferably 5 mass % or more, more preferably 10 mass % or more and still more preferably 15 mass % or more of the entire primer from the viewpoint of the formability into thin films. From the viewpoint of the coatability to substrates, the total content percentage is preferably 50 mass % or less, more preferably 35 mass % or less and still more preferably 30 mass % or less of the entire primer.

The primer may include an epoxy compound other than the liquid crystalline epoxy compound as necessary. Specific examples of the epoxy compound other than the liquid crystalline epoxy compound include glycidyl ethers of a phenolic compound such as bisphenol A, bisphenol F, bisphenol S, phenolic novolac, cresol novolac, and resorcinol novolac; glycidyl ethers of an alcohol compound such as butanediol, polyethylene glycol and polypropylene glycol; glycidyl esters of a carboxylic acid compound such as phthalic acid, isophthalic acid and tetrahydrophthalic acid; glycidyl-type (including methylglycidyl-type) epoxy monomers in which active hydrogen bonding to a nitrogen atom is substituted by a glycidyl group such as aniline and isocyanuric acid; alicyclic epoxy monomers such as vinylcyclohexene epoxide, 3,4-epoxycyclohexylmethyl-3,4-epoxycyclohexanecarboxylate, 2-(3,4-epoxy)cyclohexyl-5,5-spiro(3,4-epoxy)cyclohexane-m-dioxane that are obtained by epoxidizing an olefin bond in the molecule; epoxides of bis(4-hydroxy)thioether; glycidyl ethers such as paraxylylene-modified phenolic resins, metaxylylene-paraxylylene-modified phenolic resins, terpene-modified phenolic resins, dicyclopentadiene-modified phenolic resins, cyclopentadiene-modified phenolic resins, polycyclic aromatic ring-modified phenolic resins and naphthalene ring-containing phenolic resins; stilbene-type epoxy monomers; halogenated phenolic novolac-type epoxy monomers and the like (here, among these, liquid crystalline epoxy monomers are excluded). These epoxy compounds may be used singly or two or more epoxy compounds may be jointly used.

In a case where the primer includes the epoxy compound other than the liquid crystalline epoxy compound, the content thereof is not particularly limited. For example, in a case where the mass of the liquid crystalline epoxy compound is regarded as 1, the content is preferably 0.3 or less, more preferably 0.2 or less and still more preferably 0.1 or less.

(Curing Agent)

The primer of the present embodiment contains a curing agent. The curing agent is not particularly limited as long as the curing agent is a compound capable of causing a curing reaction with the liquid crystalline epoxy monomer. Specific examples of the curing agent include an amine curing agent, an acid anhydride curing agent, a phenolic curing agent, a polymercaptan curing agent, a polyaminoamide curing agent, an isocyanate curing agent, a blocked isocyanate curing agent and the like. These curing agents may be used singly or two or more curing agents may be jointly used.

From the viewpoint of forming a liquid crystalline structure in the primer layer, the curing agent is preferably an amine curing agent or a phenolic curing agent, more preferably an amine curing agent and still more preferably an amine curing agent including meta-xylyenediamine.

In a case where a phenolic curing agent is used as the curing agent, a curing accelerator may be jointly used as necessary. The joint use of the curing accelerator makes it possible to more sufficiently cure the epoxy resin composition. The kind of the curing accelerator is not particularly limited, and the curing accelerator may be selected from curing accelerators that are normally used. Examples of the curing accelerator include an imidazole compound, a phosphine compound and a borate salt compound.

The content of the curing agent in the primer can be appropriately set in consideration of the kind of the curing agent to be blended and the physical properties of the liquid crystalline epoxy compound. Specifically, the equivalent number of a functional group of the curing agent with respect to 1 equivalent of the epoxy group in the liquid crystalline epoxy compound is preferably 0.005 equivalent to 5 equivalent, more preferably 0.01 equivalent to 3 equivalent and still more preferably 0.5 equivalent to 1.5 equivalent. When the equivalent number of the functional group of the curing agent is 0.005 equivalent or more with respect to 1 equivalent of the epoxy group, there is a tendency that it is possible to further improve the curing rate of the liquid crystalline epoxy compound. In addition, when the equivalent number of the functional group of the curing agent is 5 equivalent or less with respect to 1 equivalent of the epoxy group, there is a tendency that the curing reaction can be more appropriately controlled.

The chemical equivalent in the present specification represents the equivalent number of a hydroxyl group of a phenolic curing agent with respect to 1 equivalent of the epoxy group when, for example, a phenolic curing agent is used as the curing agent and represents the equivalent number of active hydrogen of an amine curing agent with respect to 1 equivalent of the epoxy group when an amine curing agent is used as the curing agent.

(Solvent)

The primer of the present disclosure may contain a solvent. The kind of the solvent is not particularly limited, and it is possible to use organic solvents that are in use in the production techniques of a variety of ordinary chemical products such as ketone-based solvents, alcoholic solvents, ester-based solvents, ether-based solvents and alkyl-based solvents.

Specific examples of the solvent include acetone, isobutyl alcohol, isopropyl alcohol, isopentyl alcohol, ethyl ether, ethylene glycol monoethyl ether, xylene, cresol, chlorobenzene, isobutyl acetate, isopropyl acetate, isopentyl acetate, ethyl acetate, methyl acetate, cyclohexanol, cyclohexanone, 1,4-dioxane, dichloromethane, styrene, tetrachloroethylene, tetrahydrofuran, toluene, normal hexane, 1-butanol, 2-butanol, methanol, 1-methoxy-2-propanol, methyl isobutyl ketone, methyl ethyl ketone, methylcyclohexanol, methylcyclohexanone, chloroform, carbon tetrachloride, 1,2-dichloroethane and the like. These solvents may be used singly or two or more solvents may be jointly used.

A ketone-based solvent and an alcoholic solvent are preferable from the viewpoint of the solubility of the liquid crystalline epoxy compound and the curing agent, and an alcohol solvent is more preferable from the viewpoint of the wettability to the surfaces of substrates having a surface free energy of 50 mN/m or higher and the environmental affinity.

The content percentage of the solvent that is included in the primer is preferably 50 mass % or more, more preferably 65 mass % or more and particularly preferably 70 mass % or more of the entire primer of the entire primer from the viewpoint of the coatability to the substrate. From the viewpoint of the formability into thin films, the content percentage is preferably 95 mass % or less, more preferably 90 mass % or less and still more preferably 85 mass % or less of the entire primer.

(Other Components)

The primer of the present disclosure may include components other than the epoxy compound, the curing agent and the solvent (the other components) as necessary. For example, the primer may include an inorganic filler, a coupling agent, a dispersant, an elastomer, a mold release agent or the like. In a case where the primer of the present disclosure includes the other components, the content percentage thereof is preferably 5 mass % or less of the entire primer.

The thickness (the average thickness in a case where the thickness is not constant) of the primer layer that is formed on the substrate using the primer of the present disclosure is not particularly limited. The thickness may be, for example, 30 μm or less, may be 20 μm or less or may be 10 μm or less. When the thickness of the primer layer is 30 μm or less, the molecules of the liquid crystalline epoxy compound are likely to be oriented in the thickness direction, and the primer layer tends to be excellent in terms of the thermal conductive properties in the thickness direction. In addition, the probability of the generation of a defect such as orientation disorder becomes low, and there is a tendency that high thermal conductivity can be stably obtained.

The average thickness of the primer layer is the arithmetic average value of values measured at 10 arbitrarily-selected sites in the primer layer.

The lower limit value of the thickness (the average thickness in a case where the thickness is not constant) of the primer layer is not particularly limited and may be 1 μm or more, may be 3 μm or more or may be 5 μm or more from the viewpoint of the joint strength.

<Substrate Equipped with Primer Layer>

A substrate equipped with a primer layer of the present disclosure is a substrate equipped with a primer layer including a substrate and a primer layer,

in which the primer layer is a cured product of the above-described primer, and

the surface free energy of the surface of the substrate facing the primer layer is 50 mN/m or higher.

The substrate equipped with a primer layer having the above-described configuration is excellent in terms of thermal conductive properties and excellent in terms of the joint strength between the primer layer and the substrate.

(Substrate)

The material of the substrate that is included in the substrate equipped with a primer layer is not particularly limited, and examples thereof include metal, semiconductors, ceramic, glass and the like. Among these, metal having high thermal conductive properties and a large thermal capacity is preferable.

The metal can be appropriately selected from materials that are normally used such as copper, aluminum, iron, titanium and alloys including these metals. The material can be selected depending on the purpose; for example, aluminum is used in a case where weight reduction or workability is prioritized and copper is used in a case where heat dissipation properties are prioritized.

The thickness of the substrate is not particularly limited and can be appropriately selected depending on the use. From the viewpoint of the workability, the thickness (the average thickness in a case where the thickness is not constant) of a metal plate may be 0.1 mm to 10 mm.

The average thickness of the metal plate is the arithmetic average value of values measured at 10 arbitrarily-selected sites in the metal plate.

In addition, from the viewpoint of enhancing the productivity, the substrate equipped with a primer layer is preferably cut into the size in which the substrate equipped with a primer layer is to be used after a primer layer is formed on a substrate having a larger size than the necessary size and a heat dissipation material, an electronic component and the like are mounted thereon. In this case, a material that is used as the substrate is desirably excellent in terms of cuttability.

(Surface Roughness of Metal Plate)

From the viewpoint of the joint strength between the metal plate and the primer layer, the arithmetic surface roughness Ra (hereinafter, also simply referred to as the surface roughness) of the surface of the substrate facing the primer layer is preferably 1.0 μm or more, more preferably 1.2 μm or more and still more preferably 1.6 μm or more.

When the surface roughness of the surface of the substrate facing the primer layer is 1.0 μm or more, the primer layer enters the uneven structure of the surface of the substrate to generate a mechanical bond (also referred to as the anchoring effect), and there is a tendency that the joint strength further increases.

The surface roughness of the substrate is preferably 25 μm or less, more preferably 12.5 μm or less and still more preferably 6.3 μm or less from the viewpoint of making it easy for the molecules of the liquid crystalline epoxy compound to be oriented perpendicular to the surface of the substrate and increasing the thermal conductivity of the primer layer.

The arithmetic surface roughness (Ra) refers to a value expressed in micrometers (μm) that is obtained from the following expression (1) when a portion that is as long as the standard length in a direction of the average line of the roughness curve of a surface to be measured is removed from the roughness curve, the direction of the average line of the removed portion is regarded as the X axis, the direction of vertical magnification is regarded as the Y axis and the roughness is expressed by a roughness curve y=f(x).

$$\begin{matrix}[ Math . 1 ] & \\ Ra = \frac{l}{ℓ} {\int }_{O}^{ℓ} \{ f ( x ) \} dx & ( 1 )\end{matrix}$$

The arithmetic surface roughness in the present disclosure is defined as a value that is obtained from the roughness curve that is measured by installing the substrate in a direction in which the maximum height Rz of the surface to be measured of the substrate is maximized when the cut-off value is set to 0.8 mm and the standard length of the roughness curve is set to 4 mm.

The maximum height Rz refers to a value expressed in micrometers (μm) that is obtained from the following expression (2) by removing a portion that is as long as the standard length in the direction of the average line of the roughness curve from the roughness curve and measuring the intervals with the peak line and the valley line (Rp and Rv) of the removed portion in the direction of vertical magnification of the roughness curve.

Rz=Rp+Rv (2)

The method for measuring the surface roughness of the substrate is not particularly limited and can be selected from, for example, a stylus scanning method, which is a contact type roughness measurement method, a laser probe method, a patterned light projection method, and a white light interference method, which are non-contact type roughness measurement methods, and the like.

The surface roughness of the substrate can be adjusted by carrying out a surface treatment of the substrate. The method for the surface treatment is not particularly limited, and examples thereof include an etching method, a polishing method and the like.

(Surface Free Energy of Substrate)

The surface free energy of the surface of the substrate facing the primer layer is preferably 55 mN/m or higher, more preferably 60 mN/m or higher and more preferably 70 mN/m or higher from the viewpoint of the joint strength.

In the present disclosure, the surface free energy of the substrate is obtained based on the contact angles of water, diiodomethane and n-hexadecane that are measured under conditions of 25° C. and a relative humidity of 50%. The specific method is as described below.

The surface free energy (γₛ) of the substrate is represented by the sum of the dispersion term (γ^{d}ₛ) of the surface free energy and the polarity term (γ^{p}ₛ) of the surface free energy as shown in the following equation (4).

γₛ=γ^{d}ₛ+γ^{p}ₛ (4)

The surface free energy (γ_{L}) of a liquid is represented by the sum of the dispersion term (γ^{d}_{L}) of the surface free energy and the polarity term WO of the surface free energy as shown in the following equation (5).

γ_{L}=γ^{d}_{L}+γ^{p}_{L} (5)

The polarity term (γ^{p}ₛ) of the surface free energy of the substrate can be obtained with the following equation (6) from the contact angle to the substrate of a liquid for which, in the surface free energy (γ_{L}) of the liquid, the values of both the dispersion term (γ^{d}_{L}) and the polarity term (γ^{p}_{L}) are already known. In the equation (6), θ indicates the contact angle between the substrate and the liquid. “Contact angle” mentioned herein is an angle formed between the tangent line to a liquid droplet at an end point of the interface between the liquid droplet and the substrate and the surface of the substrate.

$$\begin{matrix}[ Math . 2 ] & \\ {γ}_{L} ( 1 + cos θ ) = 2 \sqrt{{γ}_{L}^{d} {γ}_{S}^{d}} + 2 \sqrt{{γ}_{L}^{p} {γ}_{S}^{p}} & ( 6 )\end{matrix}$$

The equation (6) is converted to the following equation (9).

$$\begin{matrix}[ Math . 3 ] & \\ \frac{{γ}_{L} ( 1 + cos θ )}{2 \sqrt{{γ}_{L}^{d}}} = \sqrt{{γ}_{S}^{p}} \cdot \frac{\sqrt{{γ}_{L}^{p}}}{\sqrt{γ \frac{d}{L}}} + \sqrt{{γ}_{S}^{d}} & ( 9 )\end{matrix}$$

The square root of each of the dispersion term (γ^{d}_{L}) of 29.3 mN/m and the polarity term (γ^{p}_{L}) of 43.5 mN/m of the surface free energy of water is calculated, the square root of the polarity term is divided by the square root of the dispersion term, and the obtained value of 1.23 is regarded as X1. The contact angle of water is assigned into the left-hand side term of the equation (9), and the obtained value of 6.75 (1+COS θ_{(water)}) is regarded as Y1. That is, the equation into which the dispersion term and polarity term of the surface free energy of water and the contact angle of water have been assigned is converted to an equation (10).

X1=1.23, Y1=6.75(1+COS θ_{(water)}) (10)

Next, the square root of each of the dispersion term (γ^{d}_{L}) of 46.8 mN/m and the polarity term (γ^{p}_{L}) of 4 mN/m of the surface free energy of diiodomethane is calculated, the square root of the polarity term is divided by the square root of the dispersion term, and the obtained value of 0.29 is regarded as X2. The contact angle of diiodomethane is assigned into the left-hand side term of the equation (9), and the obtained value of 3.71 (1+COS θ_{(diiodomethane)}) is regarded as Y2. That is, the equation into which the dispersion term and polarity term of the surface free energy of diiodomethane and the contact angle of diiodomethane have been assigned is converted to an equation (11).

X2=0.29, Y2=3.71(1+COS θ_{(diiodomethane)}) (11)

Next, the square root of each of the dispersion term (γ^{d}_{L}) of 27.6 mN/m and the polarity term (γ^{p}_{L}) of 0 mN/m of the surface free energy of n-hexadecane is calculated, the square root of the polarity term is divided by the square root of the dispersion term, the obtained value of 0 is regarded as X3, the contact angle of n-hexadecane is assigned into the left-side term of the equation (9), and the obtained value of 2.63 (1+COS θ_{(n-hexadecane)}) is regarded as Y3. That is, the equation into which the dispersion term and polarity term of the surface free energy of n-hexadecane and the contact angle of n-hexadecane have been assigned is converted to an equation (12).

X3=0, Y3=2.63(1+COS θ_{(n-hexadecane)}) (12)

The coordinates (X1, Y1), (X2, Y2) and (X3, Y3) that are obtained from the equation (10), the equation (11) and the equation (12) are plotted in a scatter plot in which X is plotted along the horizontal axis and Y is plotted along the vertical axis, the intercept of an approximation straight line by the least-square method of these plots is indicated by a, and the slope is indicated by b. The dispersion term (γ^{d}ₛ) of the surface free energy of the substrate is obtained from the square of a, and the polarity term (γ^{p}ₛ) of the surface free energy of the substrate is obtained from the square of b.

The surface free energy (γₛ) of the substrate is obtained as the sum of the dispersion term (γ^{d}ₛ) of the surface free energy and the polarity term (γ^{p}ₛ) of the surface free energy from the equation (4).

The substrate having a surface free energy of 50 mN/m or higher can be obtained by, for example, carrying out an oxidation treatment on the substrate. Examples of the method for the oxidation treatment include a heating treatment, ultraviolet irradiation, an ozone treatment, an O₂ plasma treatment, an atmospheric pressure plasma treatment, a chromic acid treatment and the like. Among these, the heating treatment and the ultraviolet irradiation are preferable.

The heating treatment of the substrate can be carried out by an ordinary method. In the heating treatment, it is possible to use an ordinary heating device that is in use in the production techniques of a variety of chemical products such as a hot plate, a constant-temperature vessel, an electric furnace and a firing furnace. The atmosphere of the heating treatment is not particularly limited, but an oxygen atmosphere such as under the atmosphere is preferable from the viewpoint of increasing the concentration of oxygen atoms on the surface of the substrate. In addition, the heating time is not particularly limited, but is preferably 1 minute or longer and more preferably 10 minutes or longer from the viewpoint of decomposing an organic impurity on the surface of the substrate.

The ultraviolet irradiation of the substrate can be carried out by an ordinary method. For example, the ultraviolet irradiation can be carried out using an ultraviolet irradiation device that is in use in the production techniques of a variety of chemical products such as a high-pressure mercury lamp, a low-pressure mercury lamp, a deuterium lamp, a metal halide lamp, a xenon lamp or a halogen lamp. Ultraviolet rays that are used for the irradiation preferably include light including an ultraviolet wavelength region of 150 nm to 400 nm and may include light having the other wavelengths. The ultraviolet rays preferably include light including an ultraviolet wavelength region of 150 nm to 400 nm from the viewpoint of decomposing an organic impurity on the surface of the substrate.

The irradiation intensity of the ultraviolet rays is not particularly limited, but is preferably 0.5 mW/cm² or higher. At this irradiation intensity, there is a tendency that an intended effect is more sufficiently exhibited. The irradiation time is preferably 10 seconds or longer in order to more sufficiently exhibit the intended effect.

The amount of the ultraviolet irradiation is specified by irradiation intensity (mW/cm²)×irradiation time (seconds) and is preferably 100 mJ/cm² or higher, more preferably 1000 mJ/cm² or higher, still more preferably 5000 mJ/cm² or higher and particularly preferably 10000 mJ/cm² or higher from the viewpoint of more sufficiently exhibiting the intended effect. In addition, the amount of the ultraviolet irradiation is preferably 50000 mJ/cm² or lower from the viewpoint of further suppressing the damaging of the substrate due to the ultraviolet irradiation. The range of the amount of the ultraviolet irradiation is preferably 100 mJ/cm² to 50000 mJ/cm², more preferably 1000 mJ/cm² to 50000 mJ/cm² and still more preferably 5000 mJ/cm² to 50000 mJ/cm². The ultraviolet irradiation intensity is specified by a method that is described in examples to be described below.

In the ultraviolet irradiation treatment, the metal plate is preferably irradiated with, for example, 100 JW/cm² or more of light including ultraviolet rays having a wavelength of 150 nm to 400 nm.

In addition, the ultraviolet irradiation atmosphere is not limited, but is preferably in the presence of oxygen or in the presence of ozone from the viewpoint of increasing the concentration of oxygen atoms on the surface of the metal plate.

(Primer Layer)

The primer layer in the substrate equipped with a primer layer of the present disclosure is a cured product of the primer including the liquid crystalline epoxy compound and the curing agent and thus includes a liquid crystalline structure. The primer layer preferably further includes the molecules of the liquid crystalline epoxy compound oriented in a direction perpendicular to the surface of the substrate from the viewpoint of the thermal conductive properties.

Whether or not the molecules of the liquid crystalline epoxy compound are oriented in a direction perpendicular to the surface of the substrate in the primer layer can be inspected using, for example, a polarizing microscope. Specifically, in a case where the primer layer is observed with a polarizing microscope (for example, manufactured by Nikon Instruments Inc., trade name: “OPTIPHOT2-POL”) and becomes a dark visual field in orthoscopic observation under crossed-Nicols and the Maltese cross can be observed in conoscopic observation, it is possible to determine that the molecules of the liquid crystalline epoxy compound are oriented in a direction perpendicular to the surface of the substrate in the primer layer.

The details and preferable aspects of the primer that is used to form the primer layer and the components that are included in the primer are the same as those of the above-described primer.

The thickness (the average thickness in a case where the thickness is not constant) of the primer layer is not particularly limited and can be selected depending on the use or the like of the substrate equipped with a primer layer. The thickness may be, for example, 30 μm or less, may be 20 μm or less or may be 10 μm or less. When the thickness of the primer layer is 30 μm or less, the molecules of the liquid crystalline epoxy compound are likely to be oriented in the thickness direction, and the primer layer tends to be excellent in terms of the thermal conductive properties in the thickness direction. In addition, the probability of the generation of a defect such as orientation disorder becomes low, and there is a tendency that high thermal conductivity can be stably obtained.

The lower limit value of the thickness of the primer layer is not particularly limited and may be 1 μm or more, may be 2.5 μm or more or may be 5 μm or more from the viewpoint of the joint strength.

<Method for Producing Substrate Equipped with Primer Layer>

A method for producing a substrate equipped with a primer layer of the present disclosure is a method for producing a substrate equipped with a primer layer including a step of forming a layer including the above-described primer on a substrate and

a step of forming a primer layer by curing the layer including the primer,

in which the surface free energy of the surface of the substrate facing the primer layer is 50 mN/m or higher.

The method for forming the layer including the primer on the substrate is not particularly limited, and examples thereof include a drip method, a bar coating method, a spin coating method and the like. From the viewpoint of forming a layer having a uniform thickness, the spin coating method is preferable. The spin rate in the spin coating method is not particularly limited, but is preferably 50 rpm (rotations/minute) to 5000 rpm and more preferably 100 rpm to 3000 rpm. The temperature of the primer at the time of forming the layer including the primer on the substrate is not particularly limited, but is preferably 150° C. or lower and more preferably 100° C. or lower in order to prevent curing from excessively progressing.

The step of forming the primer layer by curing the layer including the primer formed on the substrate may be divided into a step of putting the layer including the primer into a semi-cured state and a method for forming the primer layer by completely curing the layer in a semi-cured state.

“Semi-cured state” in the present disclosure refers to a state where some of the epoxy compound and some of the curing agent that are included in the primer have been reacted with each other (that is, some of the epoxy compound and some of the curing agent remain in an unreacted state).

When the layer including the primer is put into the semi-cured state, it is possible to increase the joint strength to, for example, a member that is disposed on the surface of the primer layer opposite to the substrate.

The method for putting the layer including the primer into the semi-cured state is not particularly limited, and, for example, the liquid crystalline epoxy compound and the curing agent that are included in the primer may be reacted with each other at a temperature of 150° C. or lower. Specifically, the layer including the primer may be put into the semi-cured state by adjusting the temperature of a device that is used in the spin coating method, the spin coating time or the like.

The method for forming the primer layer by curing the layer including the primer in the semi-cured state is not particularly limited, and the layer may be heated at a temperature at which the reaction between the epoxy compound and the curing agent that are included in the primer sufficiently progresses (for example, a temperature of 200° C. or lower). The heating time is not particularly limited and may be, for example, one hour to five hours or may be two hours to four hours.

A heat treatment (post curing) may be further carried out on the primer layer as necessary. When the post curing treatment is carried out, there is a tendency that the crosslinking density of the primer layer further improves.

In the method of the present disclosure, the surface free energy of the surface of a base material facing the primer layer is 50 mN/m or higher. Therefore, a liquid crystalline structure in a state where the molecules of the epoxy compound are oriented perpendicular to the substrate in the primer layer is likely to be formed, and excellent thermal conductive properties are exhibited.

<Method for Producing Semiconductor Device>

A method for producing a semiconductor device of the present disclosure is a method for producing a semiconductor device including a step of forming a layer including the above-described primer on a substrate,

a step of disposing an insulating member on the layer including the primer, and

a step of forming a primer layer by curing the layer including the primer,

in which the surface free energy of the surface of the substrate facing the primer layer is 50 mN/m or higher.

A semiconductor device that is produced by the above-described method is excellent in terms of the joint strength of the primer layer to the substrate and excellent in terms of heat dissipation properties.

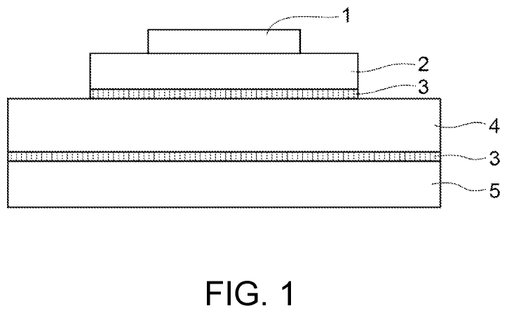

The semiconductor device that is produced by the above-described method may include a plurality of substrates and a plurality of primer layers. For example, as shown in FIG. 1, a semiconductor element 1, a substrate 2, a primer layer 3, an insulating member 4, a primer layer 3 and a substrate 5 may be disposed in this order in the structure.

A semiconductor device including a plurality of substrates and a plurality of primer layers can be produced by, for example, preparing a plurality of substrates each having a layer including the primer in a semi-cured state formed on one surface, interposing a heat dissipation member between these substrates, completely curing the layers including the primer in this state to form primer layers and then mounting a semiconductor element.

The kind of the insulating member that is used in the semiconductor device is not particularly limited. For example, the insulating member may be a filler-containing insulating heat dissipation sheet or the like having enhanced heat dissipation properties that is obtained by incorporating an inorganic filler into an insulating material such as a resin that is ordinarily used in the production of semiconductor devices.

The kind of the substrate that is used in the semiconductor device is not particularly limited. For example, in the case of producing a semiconductor module of an inverter, it is preferable to select the substrate from copper and aluminum, and it is more preferable to select copper for one substrate on which the semiconductor element is to be mounted and select aluminum for the other substrate.

### EXAMPLES

Hereinafter, the present disclosure will be more specifically described using examples, but the present disclosure is not limited these examples. Unless particularly otherwise described, “parts” and “%” are mass-based.

### Example 1

4-{4-(2,3-Epoxypropoxy)phenyl}cyclohexyl=4-(2,3-epoxypropoxy)benzoate (a compound in which, in the general formula (1), all of R¹ to R⁴ were hydrogen atoms; hereinafter, also referred to as “epoxy compound 1”) as a liquid crystalline epoxy compound, 3,3′-diaminodiphenylsulfone as a curing agent and 1-methoxy-2-propanol as a solvent were mixed together to prepare a primer.

The amounts of the epoxy compound and the curing agent blended were adjusted such that the ratio between the equivalent number of epoxy groups of the epoxy compound and the equivalent number of active hydrogen of the curing agent (epoxy group:active hydrogen) reached 1:1.

The amount of the solvent was adjusted such that the content percentage of the epoxy compound and the curing agent reaches 30 mass % of the entire amount.

The prepared primer was spin-coated at 2000 rotations/minute on an aluminum plate for which an ultraviolet irradiation treatment had been carried out on a surface facing a primer layer for 10 minutes such that the thickness after curing reached 10 μm. Subsequently, the primer was dried on a hot plate at 100° C. for two hours. After that, the primer was cured at 150° C. for four hours, thereby obtaining a substrate equipped with the primer layer.

### Example 2

A substrate equipped with a primer layer was obtained in the same manner as in Example 1 except that the aluminum substrate was changed to a copper plate for which an ultraviolet irradiation treatment had been carried out on a surface facing a primer layer for 10 minutes.

### Example 3

A substrate equipped with a primer layer was obtained in the same manner as in Example 1 except that the aluminum substrate was changed to a silicon plate for which an ultraviolet irradiation treatment had been carried out on a surface facing a primer layer for 10 minutes.

### Example 4

A primer was prepared in the same manner as in Example 1 except that, instead of a liquid crystalline epoxy compound 1, an epoxy compound including a multimer that was obtained by reacting a liquid crystalline epoxy compound 1 and 4,4′-biphenol by the following method (hereinafter, also referred to as “epoxy compound 2”) was used, and a substrate equipped with a primer layer was produced.

(Synthesis of Epoxy Compound 2)

In a 500 mL three-neck flask, 50 g of the epoxy compound 1 was weighed, and 80 g of propylene glycol monomethyl ether was added thereto as a solvent. A cooling tube and a nitrogen introduction tube were installed in the three-neck flask, and stirring blades were mounted so as to be immersed in the solvent. This three-neck flask was immersed in an oil bath (120° C.), and stirring was initiated. After the epoxy compound 1 was confirmed to dissolve and turn into a transparent solution, 4,4′-biphenol was added such that the equivalent ratio between an epoxy group and a hydroxyl group (epoxy group/hydroxyl group) reached 100/25, 0.5 g of triphenylphosphine was added as a reaction catalyst, and heating was continued at an oil bath temperature of 120° C. After the heating was continued for three hours, propylene glycol monomethyl ether was distilled away from the reaction solution under reduced pressure, and the residue was cooled to room temperature (25° C.), whereby some of the epoxy compound 1 reacted with 4,4′-biphenol to obtain an epoxy compound in a state where a multimer (prepolymer) was formed (hereinafter, also referred to as “epoxy compound 2”).

### Example 5

A primer was prepared in the same manner as in Example 2 except that, instead of the epoxy compound 1, the epoxy compound 2 was used, and a substrate equipped with a primer layer was produced.

### Example 6

A primer was prepared in the same manner as in Example 3 except that, instead of the epoxy compound 1, the epoxy compound 2 was used, and a substrate equipped with a primer layer was produced.

### Example 7

A primer was prepared in the same manner as in Example 4 except that an epoxy compound including a multimer synthesized in the same manner as the multimer in the epoxy compound 2 except that, instead of 4,4′-biphenol, 1,5-naphthalenediol was used (hereinafter, also referred to as “epoxy compound 3”) was used, and a substrate equipped with a primer layer was produced.

### Example 8

A primer was prepared in the same manner as in Example 5 except that, instead of the epoxy compound 2, the epoxy compound 3 was used, and a substrate equipped with a primer layer was produced.

### Example 9

A primer was prepared in the same manner as in Example 6 except that, instead of the epoxy compound 2, the epoxy compound 3 was used, and a substrate equipped with a primer layer was produced.

### Example 10

A primer was prepared in the same manner as in Example 4 except that an epoxy compound including a multimer synthesized in the same manner as the multimer in the epoxy compound 2 except that, instead of 4,4′-biphenol, 4-hydroxybenzoic acid was used (hereinafter, also referred to as “epoxy compound 4”) was used, and a substrate equipped with a primer layer was produced.

### Example 11

A primer was prepared in the same manner as in Example 5 except that, instead of the epoxy compound 2, the epoxy compound 4 was used, and a substrate equipped with a primer layer was produced.

### Example 12

A primer was prepared in the same manner as in Example 6 except that, instead of the epoxy compound 2, the epoxy compound 4 was used, and a substrate equipped with a primer layer was produced.

### Example 13

A primer was prepared in the same manner as in Example 4 except that an epoxy compound including a multimer synthesized in the same manner as the multimer in the epoxy compound 2 except that, instead of 4,4′-biphenol, 2-hydroxy-6-naphthoic acid was used (hereinafter, also referred to as “epoxy compound 5”) was used, and a substrate equipped with a primer layer was produced.

### Example 14

A primer was prepared in the same manner as in Example 5 except that, instead of the epoxy compound 2, the epoxy compound 5 was used, and a substrate equipped with a primer layer was produced.

### Example 15

A primer was prepared in the same manner as in Example 6 except that, instead of the epoxy compound 2, the epoxy compound 5 was used, and a substrate equipped with a primer layer was produced.

### Example 16

A primer was prepared in the same manner as in Example 1 except that, as the liquid crystalline epoxy compound, 1-(3-methyl-4-oxiranylmethoxyphenyl)-4-(oxiranylmethoxyphenyl)-1-cyclohexene (a compound in which, in the general formula (2), all of R¹ to R⁴ were hydrogen atoms; hereinafter, also referred to as “epoxy compound 6”) was used instead of the epoxy compound 1, and a substrate equipped with a primer layer was produced.

The content percentage of the liquid crystalline epoxy compound that was included in the primer was approximately 35 vol % of the total solid content of the primer.

### Example 17

A primer was prepared in the same manner as in Example 2 except that, instead of the epoxy compound 1, the epoxy compound 6 was used, and a substrate equipped with a primer layer was produced.

### Example 18

A primer was prepared in the same manner as in Example 3 except that, instead of the epoxy compound 1, the epoxy compound 6 was used, and a substrate equipped with a primer layer was produced.

### Comparative Example 1

A substrate equipped with a primer layer was produced in the same manner as in Example 1 except that the ultraviolet irradiation treatment of the aluminum plate was not carried out.

### Comparative Example 2

A substrate equipped with a primer layer was produced in the same manner as in Example 2 except that the ultraviolet irradiation treatment of the copper plate was not carried out.

### Comparative Example 3

A substrate equipped with a primer layer was produced in the same manner as in Example 3 except that the ultraviolet irradiation treatment of the silicon plate was not carried out.

### Comparative Example 4

A primer was prepared in the same manner as in Example 1 except that, instead of the epoxy compound 1, a non-liquid crystalline bisphenol A type epoxy compound (“jER828” manufactured by Mitsubishi Chemical Corporation; hereinafter, also referred to as “epoxy compound 7”) was used, and a substrate equipped with a primer layer was produced.

### Comparative Example 5

A primer was prepared in the same manner as in Example 2 except that, instead of the epoxy compound 1, the epoxy compound 7 was used, and a substrate equipped with a primer layer was produced.

### Comparative Example 6

A primer was prepared in the same manner as in Example 3 except that, instead of the epoxy compound 1, the epoxy compound 7 was used, and a substrate equipped with a primer layer was produced.

<Measurement of Thermal Resistance>

The substrate of the substrate equipped with a primer layer was removed by polishing in order to measure the thermal conductivity of the primer layer. Next, the primer layer was worked into size of 10 mm×10 mm in order to measure the thermal diffusivity of the primer layer, and the thermal diffusivity was measured using a thermal diffusivity measuring instrument “TA3” manufactured by Bethel Co., Ltd. The measurement result was multiplied by the density measured by the Archimedes method and the specific heat measured by the DSC method, thereby obtaining the thermal conductivity of an epoxy resin-cured product insulating film in the thickness direction. The thermal resistance (K/W) of the primer layer was obtained with the following equation from the obtained value of the thermal conductivity and the area (100 mm²) and average thickness measured with a micrometer of the primer layer. The results are shown in Table 1.

Thermal resistance=thickness/(thermal conductivity×area)

<Observation of Liquid Crystalline Structure and Orientation Direction>

The substrate of the substrate equipped with a primer layer was removed by polishing, and the presence or absence of a liquid crystalline structure in the primer layer and the orientation direction of the molecules of the epoxy compound were inspected by the above-described methods using a polarizing microscope (manufactured by Nikon Instruments Inc., trade name: “OPTIPHOT2-POL”).

In a case where a smectic structure was confirmed as the liquid crystalline structure, X-ray diffraction of the primer layer was carried out, and the period length was calculated by the above-described method. The results are shown in Table 1.

In Table 1, “Perpendicular” means that a liquid crystalline structure is observed and the molecules of the epoxy compound are oriented in a direction perpendicular to the substrate, “In-plane” means that a liquid crystalline structure is observed and the molecules of the epoxy compound are oriented in a direction parallel to the substrate, and “N/A” means that no liquid crystalline structure is observed.

<Measurement of Shear Strength>

The tensile shear strength of the substrate equipped with a primer layer was measured according to JIS K 6850 (1999). Specifically, a tensile test was carried out on a metal substrate in which a 100 mm×25 mm primer layer was formed on a 100 mm×25 mm×3 mm substrate using “AGC-100” manufactured by Shimadzu Corporation under conditions of a test rate of 1 mm/minute and a measurement temperature of 23° C. The results are shown in Table 1.

<Measurement of Surface Roughness>

The surface roughness of the surface of the substrate, which was used for the production of the substrate equipped with a primer layer, facing the primer layer was measured using a contact type surface roughness and shape measuring instrument. Specifically, the substrate was cut to 10 mm×10 mm, oil and dust on the surface were removed, the substrate was installed in a measurement direction in which, as a parameter in the height direction, Rz was maximized, the cut-off value of the roughness curve and the evaluation length of the roughness curve were set to 0.8 mm and 4 mm, respectively, and the arithmetic average roughness Ra was measured.

<Measurement of Surface Free Energy>

The surface free energy of the surface of the substrate, which was used for the production of the substrate equipped with a primer layer, facing the primer layer was measured as described below.

The substrate was cut to size of 10 mm×10 mm, and the contact angle between the substrate and water, the contact angle between the substrate and n-hexadecane and the contact angle between the substrate and diiodomethane were measured with a contact angle measuring instrument (Kyowa Interface Science Co., Ltd., device name: “FACE CONTACT ANGLE METER CAD”) under conditions of 25° C. and a relative humidity of 50%.

The surface free energy of the substrate was obtained by the above-described method using the measured values of the contact angles. The results are shown in Table 1.

TABLE 1

| | | Thermal | | Period | | Shear | Surface | Surface |
|---|---|---|---|---|---|---|---|---|
| | | resistance | Orientation | length | | strength | roughness | free energy |
| | Epoxy compound | (K/W) | direction | (nm) | Substrate | (Mpa) | (μm) | (mN/m) |
| Example 1 | Epoxy compound 1 | 0.040 | Perpendicular | 2.5 | Al | 9 | 4.2 | 74 |
| Example 2 | Epoxy compound 1 | 0.053 | Perpendicular | 2.5 | Cu | 7 | 6.5 | 69 |
| Example 3 | Epoxy compound 1 | 0.050 | Perpendicular | 2.5 | Si | 8 | 2.1 | 54 |
| Example 4 | Epoxy compound 2 | 0.034 | Perpendicular | 2.6 | Al | 12 | 4.2 | 74 |
| Example 5 | Epoxy compound 2 | 0.050 | Perpendicular | 2.6 | Cu | 9 | 6.5 | 69 |
| Example 6 | Epoxy compound 2 | 0.040 | Perpendicular | 2.6 | Si | 10 | 2.1 | 54 |
| Example 7 | Epoxy compound 3 | 0.036 | Perpendicular | 2.6 | Al | 11 | 4.2 | 74 |
| Example 8 | Epoxy compound 3 | 0.058 | Perpendicular | 2.6 | Cu | 8 | 6.5 | 69 |
| Example 9 | Epoxy compound 3 | 0.044 | Perpendicular | 2.6 | Si | 10 | 2.1 | 54 |
| Example 10 | Epoxy compound 4 | 0.034 | Perpendicular | 2.6 | Al | 11 | 4.2 | 74 |
| Example 11 | Epoxy compound 4 | 0.052 | Perpendicular | 2.6 | Cu | 9 | 6.5 | 69 |
| Example 12 | Epoxy compound 4 | 0.051 | Perpendicular | 2.6 | Si | 10 | 2.1 | 54 |
| Example 13 | Epoxy compound 5 | 0.037 | Perpendicular | 2.7 | Al | 13 | 4.2 | 74 |
| Example 14 | Epoxy compound 5 | 0.054 | Perpendicular | 2.7 | Cu | 9 | 6.5 | 69 |
| Example 15 | Epoxy compound 5 | 0.053 | Perpendicular | 2.7 | Si | 11 | 2.1 | 54 |
| Example 16 | Epoxy compound 6 | 0.050 | Perpendicular | 2.6 | Al | 12 | 4.2 | 74 |
| Example 17 | Epoxy compound 6 | 0.049 | Perpendicular | 2.6 | Cu | 9 | 6.5 | 69 |
| Example 18 | Epoxy compound 6 | 0.045 | Perpendicular | 2.6 | Si | 10 | 2.1 | 54 |
| Comparative Example 1 | Epoxy compound 1 | 0.17 | In-plane | — | Al | 7 | 4.2 | 36 |
| Comparative Example 2 | Epoxy compound 1 | 0.17 | In-plane | — | Cu | 8 | 6.5 | 35 |
| Comparative Example 3 | Epoxy compound 1 | 0.15 | In-plane | — | Si | 7 | 2.1 | 30 |
| Comparative Example 4 | Epoxy compound 7 | 0.50 | N/A | — | Al | 8 | 4.2 | 74 |
| Comparative Example 5 | Epoxy compound 7 | 0.51 | N/A | — | Cu | 8 | 6.5 | 69 |
| Comparative Example 6 | Epoxy compound 7 | 0.49 | N/A | — | Si | 7 | 2.1 | 54 |

As shown in Table 1, in the examples where the primer layer was formed on the surface of the substrate having a surface free energy of 50 mN/m or higher using the primer including the liquid crystalline epoxy compound and the curing agent, a state where the molecules of the epoxy compound were arranged perpendicular to the substrate in the primer layer was observed, the thermal resistance was low, and the joint strength was excellent.

In Comparative Examples 1 to 3 where the surface free energy of the surface of the substrate facing the primer layer was lower than 50 mN/m and Comparative Examples 4 to 6 where the primer included no liquid crystalline epoxy compounds, a state where the molecules of the epoxy compound were arranged perpendicular to the substrate in the primer layer was not observed, and the value of the thermal resistance was larger than those of the examples.

The disclosure of Japanese Patent Application No. 2020-085320 is all incorporated into the present specification by reference.

All of the documents, patent applications, and technical standards described in the present specification are adopted and incorporated into the present specification to substantially the same extent as a case where each of the documents, patent applications, and technical standards is specifically and separately incorporated by reference.

1. A primer for forming a primer layer on a surface of a substrate having a surface free energy of 50 mN/m or higher, the primer comprising:
a liquid crystalline epoxy compound; and
a curing agent.

2. The primer according to claim 1,
wherein the liquid crystalline epoxy compound comprises at least one of a structure represented by the following general formula (M-1) and a structure represented by the following general formula (M-2), 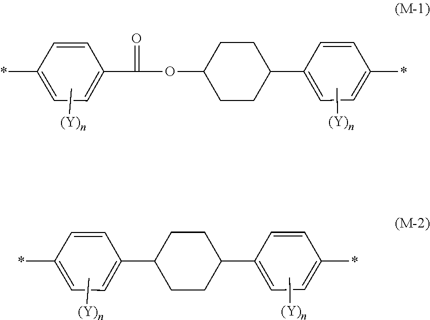
in the general formula (M-1) and the general formula (M-2), Y's each independently represent an aliphatic hydrocarbon group having 1 to 8 carbon atoms, an alkoxy group having 1 to 8 carbon atoms, a fluorine atom, a chlorine atom, a bromine atom, an iodine atom, a cyano group, a nitro group or an acetyl group, n's each independently represent an integer of 0 to 4, and * represents a bonding site to an adjacent atom.

3. The primer according to claim 2,
wherein the crystalline epoxy compound comprises a reaction product between a liquid crystalline epoxy compound comprising at least one of the structure represented by the general formula (M-1) and the structure represented by the general formula (M-2) and at least one selected from the group consisting of hydroquinone, 3,3-biphenol, 4,4-biphenol, 2,6-naphthalenediol, 1,5-naphthalenediol, 4-hydroxybenzoic acid and 2-hydroxy-6-naphthoic acid.

4. The primer according to claim 1,
wherein the curing agent comprises at least one selected from the group consisting of an amine-based curing agent and a phenolic curing agent.

5. The primer according to claim 1,
wherein a liquid crystalline structure that is formed by a reaction between the liquid crystalline epoxy compound and the curing agent is a nematic structure or a smectic structure.

6. The primer according to claim 5,
wherein the smectic structure has a periodic structure in which a length of one period is 2 nm to 4 nm.

7. The primer according to claim 1, further comprising:
an alcohols solvent.

8. The primer according to claim 1,
wherein the substrate is a metal substrate.

9. A substrate equipped with a primer layer comprising:
a substrate; and
a primer layer,
wherein the primer layer is a cured product of the primer according to claim 1, and
a surface free energy of a surface of the substrate facing the primer layer is 50 mN/m or higher.

10. A method for producing a substrate equipped with a primer layer, the method comprising:
a step of forming a layer comprising the primer according to claim 1 on a substrate; and
a step of forming a primer layer by curing the layer comprising the primer,
wherein a surface free energy of a surface of the substrate facing the primer layer is 50 mN/m or higher.

11. A semiconductor device comprising:
a substrate;
a primer layer; and
an insulating member in this order,
wherein the primer layer is a cured product of the primer according to claim 1, and
a surface free energy of a surface of the substrate facing the primer layer is 50 mN/m or higher.

12. A method for producing a semiconductor, the method comprising:
a step of forming a layer comprising the primer according to claim 1, on a substrate;
a step of disposing an insulating member on the layer comprising the primer, and
a step of forming a primer layer by curing the layer comprising the primer,
wherein a surface free energy of a surface of the substrate facing the primer layer is 50 mN/m or higher.

13. The primer according to claim 2,
wherein the curing agent comprises at least one selected from the group consisting of an amine-based curing agent and a phenolic curing agent.

14. The primer according to claim 3,
wherein the curing agent comprises at least one selected from the group consisting of an amine-based curing agent and a phenolic curing agent.

15. The primer according to claim 2,
wherein a liquid crystalline structure that is formed by a reaction between the liquid crystalline epoxy compound and the curing agent is a nematic structure or a smectic structure.

16. The primer according to claim 3,
wherein a liquid crystalline structure that is formed by a reaction between the liquid crystalline epoxy compound and the curing agent is a nematic structure or a smectic structure.

17. The primer according to claim 4,
wherein a liquid crystalline structure that is formed by a reaction between the liquid crystalline epoxy compound and the curing agent is a nematic structure or a smectic structure.

18. The primer according to claim 2, further comprising:
an alcohols solvent.

19. The primer according to claim 3, further comprising:
an alcohols solvent.

20. The primer according to claim 4, further comprising:
an alcohols solvent.
